(19) United States
(12) Patent Application Publication
(10) Pub. No.: US 2025/0252236 A1
(43) Pub. Date: Aug. 7, 2025

(54) METHOD AND SYSTEM FOR PREDICTING TOBACCO LEAF OVERRIPENESS PERIOD IN MIDDLE OF FLUE-CURED TOBACCO

(71) Applicant: Sichuan Agricultural University, Chengdu (CN)

(72) Inventors: Lei LIU, Chengdu (CN); Shuhua ZENG, Chengdu (CN); Rui CHEN, Chengdu (CN); Long YAO, Chengdu (CN); Zhenguo LI, Chengdu (CN); Liqian YANG, Chengdu (CN); Qiuyue NIE, Chengdu (CN); Xinlian DU, Chengdu (CN); Tong LI, Chengdu (CN); Fan ZHANG, Chengdu (CN); Weirong TANG, Chengdu (CN); Xin LI, Chengdu (CN); Runsheng WU, Chengdu (CN); Mengran HU, Chengdu (CN); Xiangjun CHEN, Chengdu (CN)

(21) Appl. No.: 19/027,315

(22) Filed: Jan. 17, 2025

Related U.S. Application Data
(63) Continuation of application No. PCT/CN2024/079881, filed on Mar. 4, 2024.

(30) Foreign Application Priority Data
Feb. 5, 2024 (CN) 202410162554.5

(51) Int. Cl. G06F 30/27

(52) U.S. Cl. CPC G06F 30/27

(57) ABSTRACT

A method and a system for predicting tobacco leaf overripeness period in middle of flue-cured tobacco are provided. The method includes: obtaining dates of “topping” and “middle tobacco leaf maturity” of flue-cured tobacco to be predicted, and calculating a number of days of “topping-middle tobacco leaf maturity”; and inputting the number of days of “topping-middle tobacco leaf maturity” into a preset prediction model, outputting a number of days of “topping-middle tobacco leaf overripeness” of the flue-cured tobacco to be predicted, and predicting a date when middle tobacco leaves of the flue-cured tobacco to be predicted reach an overripeness state according to the number of days of “topping-middle tobacco leaf overripeness”, wherein a prediction model is constructed based on laws of the number of days of “topping-middle tobacco leaf maturity” and the number of days of “topping-middle tobacco leaf overripeness” of the flue-cured tobacco in a time amount.

### CROSS-REFERENCE TO RELATED APPLICATIONS

This application is a continuation of PCT/CN2024/079881, filed on Mar. 4, 2024 and claims priority of Chinese Patent Application No. 202410162554.5, filed on Feb. 5, 2024, the entire contents of which are incorporated herein by reference.

### TECHNICAL FIELD

The disclosure relates to the technical field of tobacco leaf overripeness period prediction, and in particular to a method and a system for predicting tobacco leaf overripeness period in the middle of flue-cured tobacco.

### BACKGROUND

The tobacco leaf overripeness period refers to the critical period when the appearance and internal quality of tobacco leaves are obviously declined and declined after the growth and development in the field, which is no longer suitable for harvesting and processing.

Tobacco leaves need to be harvested after maturity and before overripeness, otherwise the quality will be obviously reduced. Predicting the tobacco leaf overripeness period in advance is of guiding significance in production practice, and is an important decision-making information for planning and operating various production resources in tobacco harvesting (such as harvesting personnel, transportation capacity, storage space, supporting production materials and baking processing capacity of curing barn), which is conducive to avoiding quality loss caused by harvesting overripe tobacco leaves.

At present, the way to judge the tobacco leaf overripeness period is to judge whether the tobacco leaves belong to the “overripe state” according to the appearance characteristics such as the degree of yellowing on the surface of tobacco leaves and the change of leaf shape. This method relies on manual qualitative identification on the spot to get the result. It is a qualitative, recording and description of the events that have happened. It can be used to summarize the past events, but it can not be used to predict when the “tobacco leaf overripeness period” will come. Given the important guidance of predicting the overripeness period of tobacco leaves for timely harvesting, there is an urgent need for a method and a system for predicting the tobacco leaf overripeness period in middle of flue-cured tobacco.

### SUMMARY

The objective of the disclosure is to provide a method for predicting tobacco leaf overripeness period in the middle of flue-cured tobacco, which can accurately predict when the tobacco leaf overripeness period in middle of flue-cured tobacco will come, ensure the harvesting quality of tobacco leaves, and has guiding significance for production practice.

In order to achieve the above objectives, the present disclosure provides the following scheme.

A method for predicting tobacco leaf overripeness period in middle of flue-cured tobacco, including:
obtaining dates of “topping” and “middle tobacco leaf maturity” of flue-cured tobacco to be predicted, and calculating a number of days of “topping-middle tobacco leaf maturity”; and
inputting the number of days of “topping-middle tobacco leaf maturity” into a preset prediction model, outputting a number of days of “topping-middle tobacco leaf overripeness” of the flue-cured tobacco to be predicted, and predicting a date when middle tobacco leaves of the flue-cured tobacco to be predicted reach an overripeness state according to the number of days of “topping-middle tobacco leaf overripeness”, where a prediction model is constructed based on laws of the number of days of “topping-middle tobacco leaf maturity” and the number of days of “topping-middle tobacco leaf overripeness” of the flue-cured tobacco in a time amount.

Optionally, a process of constructing the prediction model based on the laws of the number of days of “topping-middle tobacco leaf maturity” and the number of days of “topping-middle tobacco leaf overripeness” of the flue-cured tobacco in the time amount includes:
setting different levels of cultivation influencing factors and cultivating a flue-cured tobacco sample group with different growth and development progress;
recording “topping” dates of the flue-cured tobacco sample group and dates of “reaching maturity” and dates of “reaching overripeness” of the flue-cured tobacco sample group, and obtaining the number of days of “topping-middle tobacco leaf maturity” and the number of days of “topping-middle tobacco leaf overripeness” of the flue-cured tobacco sample group; and
constructing the prediction model based on a regression relationship between the number of days of “topping-middle tobacco leaf maturity” and the number of days of “topping-middle tobacco leaf overripeness” of the flue-cured tobacco sample group.

Optionally, the cultivation influencing factors include fertilization, number of leaves left and planting density.

Optionally, constructing the prediction model based on the regression relationship between the number of days of “topping-middle tobacco leaf maturity” and the number of days of “topping-middle tobacco leaf overripeness” of the flue-cured tobacco sample group includes:
constructing indexes based on the number of days of “topping-middle tobacco leaf maturity” and the number of days of “topping-middle tobacco leaf overripeness” of the flue-cured tobacco sample group;
calculating regression relationships between every two indexes, and screening out a regression relation expression with the greatest fitting degree and involving both the number of days of “topping-middle tobacco leaf maturity” and the number of days of “topping-middle tobacco leaf overripeness”, namely the prediction model.

Optionally, the indexes include the number of days of “topping-middle tobacco leaf maturity” and the number of days of “topping-middle tobacco leaf overripeness”, and derived indexes based on the number of days of “topping-middle tobacco leaf maturity” and the number of days of “topping-middle tobacco leaf overripeness”

Optionally, the derived indexes include: the number of days of “topping-middle tobacco leaf overripeness”—the number of days of “topping-middle tobacco leaf maturity”, the number of days of “topping-middle tobacco leaf maturity”+the number of days of “topping-middle tobacco leaf overripeness”, the number of days of “topping-middle tobacco leaf overripeness”/the number of days of “topping-middle tobacco leaf maturity”, the number of days of “topping-middle tobacco leaf maturity”× the number of days of “topping-middle tobacco leaf overripeness”, the number of days of “topping-middle tobacco leaf maturity”× the number of days of “topping-middle tobacco leaf maturity” and ×the number of days of “topping-middle tobacco leaf overripeness” the number of days of “topping-middle tobacco leaf overripeness”.

Optionally, the prediction model is:

d2=(d1−7.9236)/0.6783

where d2 is the number of days of “topping-middle tobacco leaf overripeness” and d1 is the number of days of “topping-middle tobacco leaf maturity”.

In order to further realize the above objective, the disclosure also provides a system for predicting tobacco leaf overripeness period in middle of flue-cured tobacco, where the system includes: an acquisition module and a prediction module;
where the acquisition module obtaining the dates of the “topping” and the “middle tobacco leaf maturity” of the flue-cured tobacco to be predicted, and calculating the number of days of “topping-middle tobacco leaf maturity”; and
the prediction module is used for inputting the number of days of “topping-middle tobacco leaf maturity” into the preset prediction model, outputting the number of days of “topping-middle tobacco leaf overripeness” of the flue-cured tobacco to be predicted, and predicting the date when the middle tobacco leaves of the flue-cured tobacco to be predicted reach the overripeness state according to the number of days of “topping-middle tobacco leaf overripeness”, where the prediction model is constructed based on the laws of the number of days of “topping-middle tobacco leaf maturity” and the number of days of “topping-middle tobacco leaf overripeness” of the flue-cured tobacco in the time amount.

The disclosure has the following beneficial effects.

According to the disclosure, ‘topping-middle tobacco leaf maturity’ days and ‘topping-middle tobacco leaf overripeness’ days are taken as basic variable indexes, and a series of derivative indexes with different calculation relationships are constructed based on the indexes, so as to further explore the laws of ‘topping-middle tobacco leaf maturity’ days and ‘topping-middle tobacco leaf overripeness’ days in time quantity, establish a regression relation expression and construct a prediction model, And the error calculation verifies that the prediction model of the disclosure is reasonable and available, has excellent effect, can accurately predict when the tobacco leaf overripeness period will come, ensures the quality of tobacco leaf harvesting, has guiding significance for production practice, can provide important decisions for the planning and operation of various production resources in tobacco leaf harvesting, and avoids the quality loss caused by harvesting overripe tobacco leaves.

### BRIEF DESCRIPTION OF THE DRAWINGS

In order to explain the embodiments of the present disclosure or the technical scheme in the prior art more clearly, the drawings needed in the embodiments will be briefly introduced below. Obviously, the drawings in the following description are only some embodiments of the present disclosure. For ordinary people in the field, other drawings can be obtained according to these drawings without paying creative labor.

FIG. 1 is a flow chart of a method for predicting the tobacco leaf overripeness period in middle of flue-cured tobacco according to an embodiment of the present disclosure.

FIG. 2 is a schematic diagram of the number of days of “topping-middle tobacco leaf maturity” and the number of days of “topping-middle tobacco leaf overripeness” of flue-cured tobacco according to the embodiment of the disclosure, where d1 is the number of days of “topping-middle tobacco leaf maturity” and d2 is the number of days of “topping-middle tobacco leaf overripeness”.

FIG. 3 is a regression analysis diagram among the selected index relation expressions with the greatest fitting degree according to an embodiment of the present disclosure.

FIG. 4 is a comparative analysis diagram between the predicted values and the measured values of the number of days of “topping-middle tobacco leaf overripeness” in an embodiment of the present disclosure.

### DETAILED DESCRIPTION OF THE EMBODIMENTS

In the following, the technical scheme in the embodiment of the disclosure will be clearly and completely described with reference to the attached drawings. Obviously, the described embodiments are only a part of the embodiments of the disclosure, but not the whole embodiments. Based on the embodiments in the present disclosure, all other embodiments obtained by ordinary technicians in the field without creative labor belong to the scope of protection of the present disclosure.

In order to make the above objects, features and advantages of the present disclosure more obvious and easy to understand, the present disclosure will be further described in detail with the attached drawings and specific embodiments.

“Maturity” and “overripeness” are two different physiological stages in the growth and development of tobacco leaves under specific environmental conditions, and is the process of orderly expression of tobacco genes and the gradual development of physiological and biochemical processes under the joint action of environmental conditions and tobacco gene expression regulation mechanism, and also is the embodiment of objective laws of biological growth and development on tobacco leaves. “Maturity” and “overripeness” are adjacent to each other in the life process of tobacco leaves, with causal relationship and orderly laws in time. The “accumulated temperature” in the environment refers to the sum of the daily average temperature in a certain period of time, which is an important index to study the relationship between temperature and the development speed of biological organisms, and can indicate the influence of temperature on the growth and development of biological organisms from two aspects: intensity and action time. Obviously, the “accumulated temperature” in the process of tobacco maturity and senescence is directly proportional to the “growth days”. Therefore, the number of days that tobacco leaves grow in the field can be regarded as the independent variable affecting tobacco leaf senescence, and the model between “growth days” and senescence can be established.

In this embodiment, the time and the number of days from the “topping” of tobacco plants to the “maturity” of fresh tobacco leaves in the middle and the time and the number of days from the “topping” to the “senescence” of fresh tobacco leaves in the middle were investigated. Taking the number of days mentioned above as the basic variable indexes, a series of derivative indexes with different calculation relationships are constructed to explore the law of time between them and establish the regression relation expression. Then, based on the regression relation expression, the tobacco leaf overripeness period is predicted according to the maturity of tobacco leaf maturity period.

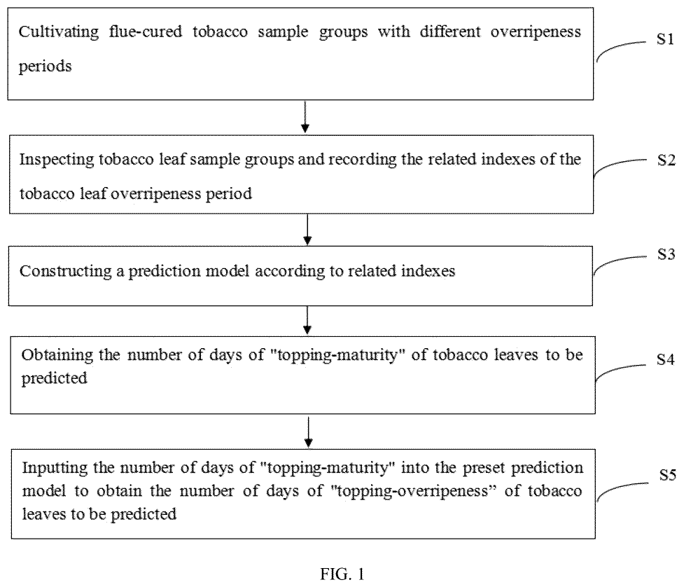

This embodiment provides a method for predicting tobacco leaf overripeness period in middle of flue-cured tobacco, as shown in FIG. 1, including:
obtaining dates of “topping” and “middle tobacco leaf maturity” of flue-cured tobacco to be predicted, and calculating a number of days of “topping-middle tobacco leaf maturity”; and
inputting the number of days of “topping-middle tobacco leaf maturity” into a preset prediction model, outputting a number of days of “topping-middle tobacco leaf overripeness” of the flue-cured tobacco to be predicted, and predicting a date when middle tobacco leaves of the flue-cured tobacco to be predicted reach an overripeness state according to the number of days of “topping-middle tobacco leaf overripeness”, where a prediction model is constructed based on laws of the number of days of “topping-middle tobacco leaf maturity” and the number of days of “topping-middle tobacco leaf overripeness” of the flue-cured tobacco in a time amount.

“Topping” refers to cutting off the whole inflorescence when the top bud of the tobacco plant is completely open, so as to terminate the reproduction and growth.

“Middle tobacco leaves mature” means that the middle leaves of tobacco plants have reached the standard of mature harvesting, and the appearance is characterized by the yellow-green to light yellow surface area of 6-7 leaves and the white and shiny main veins of ⅔ leaves.

“topping-middle tobacco leaf maturity” refers to the time from “topping” of tobacco plants to “middle tobacco leaf maturity”.

The specific process of constructing the prediction model is as follows:
step 1, cultivating flue-cured tobacco sample groups with different overripeness periods;
measures such as fertilization, number of leaves left and tobacco planting density are important factors affecting the maturity and overripeness period of tobacco leaves. In order to obtain samples of tobacco leaves with different overripeness periods, three important cultivation measures, such as fertilization amount, number of leaves left and planting density, were selected as influencing factors, and the setting level of each factor is shown in Table 1.

TABLE 1

| | Factors | | |
|---|---|---|---|
| | Fertilization amount | Number of leaves | Planting density |
| Level | (kg/hm²) | left(piece/plant) | (plant/hm²) |
| 1 | (Pure N: 90\P₂O₅: 153\ | 15leaves(B1) | 13500plants(C1) |
| | K₂O: 270)(A1) | | |
| 2 | (Pure N: 120\P₂O₅: 204 | 17leaves(B2) | 16500plants(C2) |
| | K₂O: 360)(A2) | | |
| 3 | (Pure N: 150\P₂O₅: 255\ | 19leaves(B3) | 19500plants(C3) |
| | K₂O: 450)(A3) | | |

Box-Behnken experimental design method was used to develop a response surface experimental design with 3 factors and 3 levels, including 16 treatments, as shown in Table 2.

TABLE 2

| | Experimental design | | | Factor combination | | |
|---|---|---|---|---|---|---|
| Treatment | coding table | | | Fertilization | Number of leaves | Planting density |
| number | X1 | X2 | X3 | amount (kg/hm²) | left(piece/plant) | (plant/hm²) |
| T1 | −1 | 1 | 0 | A1(Pure N: 90\ | (B3)19 | (C2)16500 |
| | | | | P₂O₅: 153\ | | |
| | | | | K₂O: 270) | | |
| T2 | 0 | 0 | 0 | A2(Pure N: 120\ | (B2)17 | (C2)16500 |
| | | | | P₂O₅: 204\ | | |
| | | | | K₂O: 360) | | |
| T3 | 0 | 1 | 1 | A2(Pure N: 120\ | (B3)19 | (C3)19500 |
| | | | | P₂O₅: 204\ | | |
| | | | | K₂O: 360) | | |
| T4 | 0 | 0 | 0 | A2(Pure N: 120\ | (B2)17 | (C2)16500 |
| | | | | P₂O₅: 204\ | | |
| | | | | K₂O: 360) | | |
| T5 | 1 | 0 | −1 | A3(Pure N: 150\ | (B2)17 | (C1)13500 |
| | | | | P₂O₅: 255\ | | |
| | | | | K₂O: 450) | | |
| T6 | 0 | 1 | −1 | A2(Pure N: 120\ | (B3)19 | (C1)13500 |
| | | | | P₂O₅: 204\ | | |
| | | | | K₂O: 360) | | |
| T7 | −1 | −1 | 0 | A1(Pure N: 90\ | (B1)15 | (C2)16500 |
| | | | | P₂O₅: 153\ | | |
| | | | | K₂O: 270) | | |
| T8 | 0 | −1 | 1 | A2(Pure N: 120\ | (B1)15 | (C3)19500 |
| | | | | P₂O₅: 204\ | | |
| | | | | K₂O: 360) | | |
| T9 | 0 | −1 | −1 | A2(Pure N: 120\ | (B1)15 | (C1)13500 |
| | | | | P₂O₅: 204\ | | |
| | | | | K₂O: 360) | | |
| T10 | 0 | 0 | 0 | A2(Pure N: 120\ | (B2)17 | (C2)16500 |
| | | | | P₂O₅: 204\ | | |
| | | | | K₂O: 360) | | |
| T11 | −1 | 0 | 1 | A1(Pure N: 90\ | (B2)17 | (C3)19500 |
| | | | | P₂O₅: 153\ | | |
| | | | | K₂O: 270) | | |
| T12 | 1 | 1 | 0 | A3(Pure N: 150\ | (B3)19 | (C2)16500 |
| | | | | P₂O₅: 255\ | | |
| | | | | K₂O: 450) | | |
| T13 | 1 | 0 | 1 | A3(Pure N: 150\ | (B2)17 | (C3)19500 |
| | | | | P₂O₅: 255\ | | |
| | | | | K₂O: 450) | | |
| T14 | 1 | −1 | 0 | A3(Pure N: 150\ | (B1)15 | (C2)16500 |
| | | | | P₂O₅: 255\ | | |
| | | | | K₂O: 450) | | |
| T15 | −1 | 0 | −1 | A1(Pure N: 90\ | (B2)17 | (C1)13500 |
| | | | | P₂O₅: 153\ | | |
| | | | | K₂O: 270) | | |
| T16 | 0 | 0 | 0 | A2(Pure N: 120\ | (B2)17 | (C2)16500 |
| | | | | P₂O₅: 204\ | | |
| | | | | K₂O: 360) | | |

The experimental field is located in Dazhai Township, Gulin County, Luzhou City, Sichuan Province. The soil is mainly yellow soil and purple soil, with heavy texture. Physical and chemical properties of soil: pH 6.49, organic matter 3.11 g/kg, alkali-hydrolyzable nitrogen 140.93 mg/kg, available phosphorus 40.06 mg/kg and available potassium 121 mg/kg. The flue-cured tobacco variety tested was Zhongchuan 208. Tobacco seedlings are transplanted in time, and 60 tobacco plants are planted in each treatment plot. Other field management measures except treatment factors should be carried out according to the plan of high-quality flue-cured tobacco cultivation management measures.

Step 2, inspecting and recording the related indexes of the tobacco leaf overripeness period.

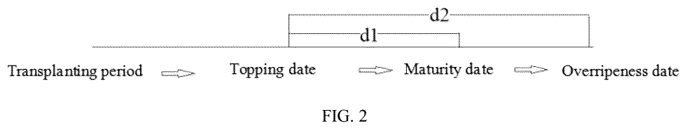

When the growth of each treated tobacco plant enters the budding topping stage, topping work is carried out to remove the inflorescence at the top of the tobacco plant, and 20 tobacco plants with normal growth are randomly selected from each treated plot, and the topping dates are recorded, and then the appearance characteristics of the middle leaves (9-11 leaves) are inspected every day, and the dates when they reach “maturity” and “overripeness” are judged and recorded, as shown in FIG. 2, d1 is the number of days of “topping-middle tobacco leaf maturity” and d2 is the number of days of “topping-middle tobacco leaf overripeness”.

The data of 20 plants of materials recorded in each treatment were used after average calculation, and the results are shown in Table 3. The values of d1 and d2 are obtained through practical investigation in the field, and “d2-d1”, “d1+d2”, “d2/d1”, “d1×d2”, “d1×d1” and “d2×d2” are all derived indexes generated by calculation.

TABLE 3

| Processing | d 1 | d 2 | d 2 − d 1 | d 1 + d 2 | | | | |
|---|---|---|---|---|---|---|---|---|
| number | (days) | (days) | (days) | (days) | d 2/d 1 | d 1 × d 2 | d 1 × d 1 | d 2 × d 2 |
| T1 | 40 | 47 | 7 | 87 | 1.18 | 1880 | 1600 | 2209 |
| T2 | 45 | 55 | 10 | 100 | 1.22 | 2475 | 2025 | 3025 |
| T3 | 42 | 51 | 9 | 93 | 1.21 | 2142 | 1764 | 2601 |
| T4 | 45 | 55 | 10 | 100 | 1.22 | 2475 | 2025 | 3025 |
| T5 | 52 | 66 | 14 | 118 | 1.27 | 3432 | 2704 | 4356 |
| T6 | 46 | 57 | 11 | 103 | 1.24 | 2622 | 2116 | 3249 |
| T7 | 40 | 47 | 7 | 87 | 1.18 | 1880 | 1600 | 2209 |
| T8 | 43 | 52 | 9 | 95 | 1.21 | 2236 | 1849 | 2704 |
| T9 | 47 | 55 | 8 | 102 | 1.17 | 2585 | 2209 | 3025 |
| T10 | 45 | 55 | 10 | 100 | 1.22 | 2475 | 2025 | 3025 |
| T11 | 39 | 46 | 7 | 85 | 1.18 | 1794 | 1521 | 2116 |
| T12 | 51 | 64 | 13 | 115 | 1.25 | 3264 | 2601 | 4096 |
| T13 | 50 | 61 | 11 | 111 | 1.22 | 3050 | 2500 | 3721 |
| T14 | 52 | 64 | 12 | 116 | 1.23 | 3328 | 2704 | 4096 |
| T15 | 41 | 49 | 8 | 90 | 1.20 | 2009 | 1681 | 2401 |
| T16 | 45 | 55 | 10 | 100 | 1.22 | 2475 | 2025 | 3025 |

Step 3, the expression of the number of days d2 of “topping-middle tobacco leaf overripeness”, that is, the prediction model is constructed.

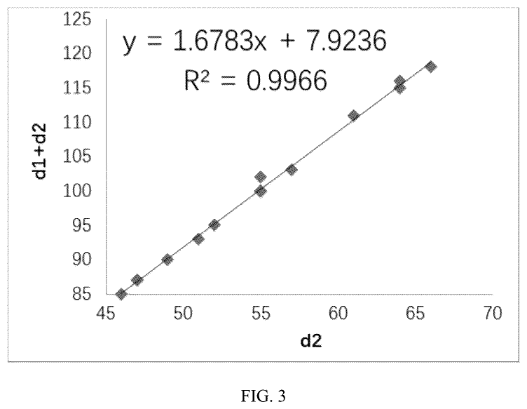

In order to explore the relationship between the number of days d1 of “topping-middle tobacco leaf maturity” and the number of days d2 of “topping-middle tobacco leaf overripeness”, the regression relationship between these indexes was calculated, so as to screen out the relationship expression with the greatest fitting degree involving both d1 and d2. The expressions reflecting the regression relationship between d1 and d2 based on the indexes in Table 3 are shown in Table 4. The range of R² value of each regression equation in the table is [0.5573-0.9966], and most of the R² values are above 0.8, which shows that there is an obvious and regular correlation between d1 and d2 in the process of tobacco senescence, showing a high degree of correlation. The relationship expression with the largest R² value is y=1.6783x+7.9236, R²=0.9966, where the x variable is d2 and the y variable is d1+d2. The regression analysis is shown in FIG. 3.

It shows that this relationship expression can best reflect the relationship between d1 and d2 among the indexes involved.

The independent variable x is substituted for “d2” and the dependent variable y for “d1+d2”, the following expression can be obtained:

d1+d2=1.6783×d2+7.9236

d1-7.9236-0.6783×d2

The final formula, namely the prediction model, is: d2=(d1−7.9236)/0.6783.

Thus, a relationship expression with d1 as the independent variable and d2 as the dependent variable is obtained. After the number of days d1 of “topping-middle tobacco leaf maturity” is known through field investigation, the number of days d2 of “topping-middle tobacco leaf overripeness” can be obtained by using this relationship expression, and the specific date of reaching the overripeness state in the future can be further predicted.

TABLE 4

| | | y variable | | | | | | |
|---|---|---|---|---|---|---|---|---|
| | | d 2 | d 2 − d 1 | d 1 + d 2 | d 2/d 1 | d 1 × d 2 | d 1 × d 1 | d 2 × d 2 |
| x variable | d 1 | y = | y = | y = | y = | y = | | y = |
| | | 1.4444x − | 0.4444x − | 2.4444x − | 0.005x + | 121.84x − | | 161.18x − |
| | | 10.333 | 10.333 | 10.333 | 0.9869 | 2998.1 | | 4228 |
| | | R² = | R² = | R² = | R² = | R² = | | R² = |
| | | 0.9798 | 0.8209 | 0.9928 | 0.5633 | 0.9912 | | 0.9754 |
| | d 2 | | y = | y = | y = | y = | y = | |
| | | | 0.3217x − | 1.6783x + | 0.0038x + | 83.61x − | 62.068x − | |
| | | | 7.9236 | 7.9236 | 1.0032 | 2085.7 | 1350.5 | |
| | | | R² = | R² = | R² = | R² = | R² = | |
| | | | 0.9159 | 0.9966 | 0.699 | 0.9939 | 0.9781 | |
| | d 2 − d 1 | | | y = | y = | y = | y = | y = |
| | | | | 4.694x + | 0.0131x + | 233.59x + | 169.02x + | 318.44x − |
| | | | | 54.358 | 1.0865 | 230.13 | 411.38 | 49.642 |
| | | | | R² = | R² = | R² = | R² = | R² = |
| | | | | 0.881 | 0.9161 | 0.8766 | 0.8195 | 0.9162 |
| | d 2/d 1 | | | | | y = | y = | y = |
| | | | | | | 14560x − | 10216x − | 20315x − |
| | | | | | | 15166 | 10342 | 21604 |
| | | | | | | R² = | R² = | R² = |
| | | | | | | 0.634 | 0.5573 | 0.694 |
| | d 1 × d 2 | | | | | | y = | y = |
| | | | | | | | 0.7459x + | 1.3305x − |
| | | | | | | | 188.91 | 281.18 |
| | | | | | | | R² = | R² = |
| | | | | | | | 0.9934 | 0.9955 |
| | d 1 × d 1 | | | | | | | y = |
| | | | | | | | | 1.7623x − |
| | | | | | | | | 573.94 |
| | | | | | | | | R² = |
| | | | | | | | | 0.9781 |

In order to further optimize the technical scheme, this embodiment also provides a system for predicting tobacco leaf overripeness period in middle of flue-cured tobacco, which includes an acquisition module and a prediction module;
where the acquisition module obtaining the dates of the “topping” and the “middle tobacco leaf maturity” of the flue-cured tobacco to be predicted, and calculating the number of days of “topping-middle tobacco leaf maturity”; and
the prediction module is used for inputting the number of days of “topping-middle tobacco leaf maturity” into the preset prediction model, outputting the number of days of “topping-middle tobacco leaf overripeness” of the flue-cured tobacco to be predicted, and predicting the date when the middle tobacco leaves of the flue-cured tobacco to be predicted reach the overripeness state according to the number of days of “topping-middle tobacco leaf overripeness”, where the prediction model is constructed based on the laws of the number of days of “topping-middle tobacco leaf maturity” and the number of days of “topping-middle tobacco leaf overripeness” of the flue-cured tobacco in the time amount.

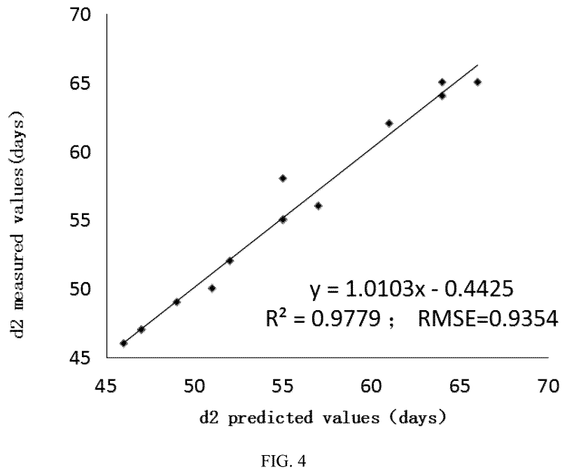

In order to test the application effect of this embodiment, the measured value d1 in Table 5 is substituted into the prediction model to find the predicted value d2′, and the relative error between d2′ and d2 is calculated. The results are shown in Table 5 below, and the comparative analysis between d2′ and d2 is shown in FIG. 4.

TABLE 5

| | | | | Relative error |
|---|---|---|---|---|
| | | | Predicted value | of predicted |
| | Measured | Measured | d2′(ŷi) d2′ = | value d2′ and |
| | d1 | d2(yi) | (d1 −7.9236)/0.6783 | measured d2(%) |
| T1 | 40 | 47 | 47 | 0 |
| T2 | 45 | 55 | 55 | 0 |
| T3 | 42 | 51 | 50 | −1.96 |
| T4 | 45 | 55 | 55 | 0 |
| T5 | 52 | 66 | 65 | −1.51 |
| T6 | 46 | 57 | 56 | −1.75 |
| T7 | 40 | 47 | 47 | 0 |
| T8 | 43 | 52 | 52 | 0 |
| T9 | 47 | 55 | 58 | 5.45 |
| T10 | 45 | 55 | 55 | 0 |
| T11 | 39 | 46 | 46 | 0 |
| T12 | 51 | 64 | 64 | 0 |
| T13 | 50 | 61 | 62 | 1.64 |
| T14 | 52 | 64 | 65 | 1.56 |
| T15 | 41 | 49 | 49 | 0 |
| T16 | 45 | 55 | 55 | 0 |

| | |
|---|---|
| Root-mean-square error RMSE | 0.9354 |

The relative errors between all the predicted values d2′ and d2 are between-1.96% and 5%, and most of them are within +2%. The root mean square error (RMSE) is used as indexes to measure the error of the prediction results. RMSE=√(Σ(yi−ŷi)²/n), where yi is the measured value, ŷi is the predicted value, and n is the number of samples. When the root mean square error range is less than 2, the model is reasonable and available, and the RMSE=0.9354 of the prediction model in this example is less than 2, which proves that the obtained model has excellent prediction effect and excellent availability.

The above-mentioned embodiment is only a description of the preferred mode of the disclosure, and does not limit the scope of the disclosure. Under the premise of not departing from the design idea and spirit of the disclosure, various modifications and improvements made by ordinary technicians in the field to the technical scheme of the disclosure shall fall within the protection scope determined by the claims of the disclosure.

1. A method for predicting tobacco leaf overripeness period in middle of flue-cured tobacco, comprising:
obtaining dates of “topping” and “middle tobacco leaf maturity” of flue-cured tobacco to be predicted, and calculating a number of days of “topping-middle tobacco leaf maturity”; and
inputting the number of days of “topping-middle tobacco leaf maturity” into a preset prediction model, outputting a number of days of “topping-middle tobacco leaf overripeness” of the flue-cured tobacco to be predicted, and predicting a date when middle tobacco leaves of the flue-cured tobacco to be predicted reach an overripeness state according to the number of days of “topping-middle tobacco leaf overripeness”, wherein a prediction model is constructed based on laws of the number of days of “topping-middle tobacco leaf maturity” and the number of days of “topping-middle tobacco leaf overripeness” of the flue-cured tobacco in a time amount, wherein the prediction model is:
d2=(d1−7.9236)/0.6783
wherein d2 is the number of days of “topping-middle tobacco leaf overripeness” and d1 is the number of days of “topping-middle tobacco leaf maturity”.

2. The method for predicting the tobacco leaf overripeness period in the middle of the flue-cured tobacco according to claim 1, wherein a process of constructing the prediction model based on the laws of the number of days of “topping-middle tobacco leaf maturity” and the number of days of “topping-middle tobacco leaf overripeness” of the flue-cured tobacco in the time amount comprises:
setting different levels of cultivation influencing factors and cultivating a flue-cured tobacco sample group with different growth and development progress;
recording “topping” dates of the flue-cured tobacco sample group and dates of “reaching maturity” and dates of “reaching overripeness” of the flue-cured tobacco sample group, and
obtaining the number of days of “topping-middle tobacco leaf maturity” and the number of days of “topping-middle tobacco leaf overripeness” of the flue-cured tobacco sample group; and
constructing the prediction model based on a regression relationship between the number of days of “topping-middle tobacco leaf maturity” and the number of days of “topping-middle tobacco leaf overripeness” of the flue-cured tobacco sample group.

3. The method for predicting the tobacco leaf overripeness period in the middle of the flue-cured tobacco according to claim 2, wherein the cultivation influencing factors comprise fertilization, number of leaves left and planting density.

4. The method for predicting the tobacco leaf overripeness period in the middle of the flue-cured tobacco according to claim 2, wherein constructing the prediction model based on the regression relationship between the number of days of “topping-middle tobacco leaf maturity” and the number of days of “topping-middle tobacco leaf overripeness” of the flue-cured tobacco sample group comprises:
constructing indexes based on the number of days of “topping-middle tobacco leaf maturity” and the number of days of “topping-middle tobacco leaf overripeness” of the flue-cured tobacco sample group; and
calculating regression relationships between every two indexes, and screening out a regression relation expression with a greatest fitting degree and involving both the number of days of “topping-middle tobacco leaf maturity” and the number of days of “topping-middle tobacco leaf overripeness”, namely the prediction model.

5. The method for predicting the tobacco leaf overripeness period in the middle of the flue-cured tobacco according to claim 4, wherein the indexes comprise the number of days of “topping-middle tobacco leaf maturity” and the number of days of “topping-middle tobacco leaf overripeness”, and derived indexes based on the number of days of “topping-middle tobacco leaf maturity” and the number of days of “topping-middle tobacco leaf overripeness”.

6. The method for predicting the tobacco leaf overripeness period in the middle of the flue-cured tobacco according to claim 5, wherein the derived indexes comprise: the number of days of “topping-middle tobacco leaf overripeness”—the number of days of “topping-middle tobacco leaf maturity”, the number of days of “topping-middle tobacco leaf maturity”+the number of days of “topping-middle tobacco leaf overripeness”, the number of days of “topping-middle tobacco leaf overripeness”/the number of days of “topping-middle tobacco leaf maturity”, the number of days of “topping-middle tobacco leaf maturity”× the number of days of “topping-middle tobacco leaf overripeness”, the number of days of “topping-middle tobacco leaf maturity”×the number of days of “topping-middle tobacco leaf maturity” and ×the number of days of “topping-middle tobacco leaf overripeness” the number of days of “topping-middle tobacco leaf overripeness”.

7. (canceled)

8. A system for predicting tobacco leaf overripeness period in middle of flue-cured tobacco, being used for implementing the method for predicting the tobacco leaf overripeness period in the middle of the flue-cured tobacco according to claim 1, wherein the system comprises: an acquisition module and a prediction module;
wherein the acquisition module is used for obtaining the dates of the “topping” and the “middle tobacco leaf maturity” of the flue-cured tobacco to be predicted, and calculating the number of days of “topping-middle tobacco leaf maturity”; and
the prediction module is used for inputting the number of days of “topping-middle tobacco leaf maturity” into the preset prediction model, outputting the number of days of “topping-middle tobacco leaf overripeness” of the flue-cured tobacco to be predicted, and predicting the date when the middle tobacco leaves of the flue-cured tobacco to be predicted reach the overripeness state according to the number of days of “topping-middle tobacco leaf overripeness”,
wherein the prediction model is constructed based on the laws of the number of days of “topping-middle tobacco leaf maturity” and the number of days of “topping-middle tobacco leaf overripeness” of the flue-cured tobacco in the time amount.
